(19) United States
(12) Patent Application Publication
(10) Pub. No.: US 2026/0214811 A1
(43) Pub. Date: Jul. 23, 2026

(54) METHOD FOR PROCESSING WORKPIECE

(71) Applicant: ORC MANUFACTURING CO., LTD., Tokyo (JP)

(72) Inventors: Akira NAKAZAWA, Machida-shi (JP); Kohei YAMABE, Machida-shi (JP); Junya ASAKURA, Machida-shi (JP); Hiromu KOBAYASHI, Machida-shi (JP)

(73) Assignee: ORC MANUFACTURING CO., LTD., Tokyo (JP)

(21) Appl. No.: 19/088,093

(22) Filed: Mar. 24, 2025

(30) Foreign Application Priority Data
Jan. 20, 2025 (JP) 2025-007950

(51) Int. Cl. H05K 3/10

(52) U.S. Cl. CPC H05K 3/105; H05K 2203/107

(57) ABSTRACT

A method for processing a workpiece, includes: a) preparing a mask with a plurality of mask patterns; b) scanning a mask with a line-shaped laser beam by a scanning mechanism, the mask being mounted on a mask stage, the plurality of mask patterns being aligned in scanning bands corresponding to the width of the line-shaped laser beam; c) projecting a pattern beam that passes through the mask onto a workpiece mounted on a processing stage to form a processed pattern in a processing area on the workpiece; and d) adjusting a processing start-position on the workpiece by controlling at least one of the mask stage, the processing stage or the scanning mechanism, in accordance to processing sections in the processing area, the processing sections being defined for at least one mask pattern.

### BACKGROUND OF THE INVENTION

### 1. Field of the Invention

The present invention relates to a laser-processing unit that forms a pattern on a workpiece such as a substrate by laser ablation using a laser beam with high energy density, and it especially relates to a laser-processing method using a mask with a plurality of mask patterns.

### 2. Description of the Related Art

A laser ablation process can accurately form a pattern on a substrate such as a printed wiring board. In a laser-processing unit or machine, a laser beam is scanned over a mask (photomask) and part of the laser beam that passes through a mask pattern is projected onto a substrate. A laser beam with high energy density melts or evaporates the surface of the substrate to form a processed pattern such as a via hole or a trench for wiring in the substrate.

Suwa et al. (US2021/0046584A1) discloses a laser-processing unit with a line-beam forming optical unit, which forms a line-shaped laser beam. A scanning mechanism moves the line-beam forming optical unit to scan the line-shaped laser beam over a mask.

Pattern arrangement throughout the mask depends upon a pattern to be processed on a substrate. The width of a line-shaped laser beam is shorter than the size of the mask due to energy density of the line-shaped laser beam and the like. Therefore, a laser ablation process for the entire processing area is accomplished by scanning the line-shaped laser beam over the mask in a controlled order.

For example, when a processed pattern overlaps with a previously formed semiconductor package substrate, processed patterns such as via holes are formed apart from one another. In this case, a region that does not include a mask pattern on the mask is scanned.

Also, a user occasionally desires the formation of different processed patterns in multiple processing areas on a single substrate. This requires the preparation of different masks for processing areas.

### SUMMARY OF THE INVENTION

A method for processing a workpiece according to the present invention, includes: a) preparing a mask with a plurality of mask patterns; b) scanning a mask with a line-shaped laser beam by a scanning mechanism, the mask being mounted on a mask stage, the plurality of mask patterns being aligned in scanning bands corresponding to the width of the line-shaped laser beam; c) projecting a pattern beam that passes through the mask onto a workpiece mounted on a processing stage to form a processed pattern in a processing area on the workpiece; and d) adjusting a processing start-position on the workpiece by controlling at least one of the mask stage, the processing stage or the scanning mechanism, in accordance to processing sections in the processing area, the processing sections being defined for at least one mask pattern.

### BRIEF DESCRIPTION OF THE DRAWINGS

The present invention will be better understood from the description of the preferred embodiment of the invention set forth below together with the accompanying drawings, in which:

FIG. 1 is a schematic view showing a laser-processing unit according to the present embodiment;

FIG. 2 is a block diagram of the laser-processing unit;

FIG. 3A illustrates a mask pattern formed on a mask and a processed pattern formed on a substrate;

FIG. 3B illustrates scanning areas and processing areas;

FIG. 4 illustrates a mask with a mask pattern different from the mask pattern in FIG. 3A;

FIG. 5 illustrates a processed pattern different from the processed pattern shown in FIG. 3B;

FIG. 6 is a flowchart of a laser ablation process;

FIG. 7 illustrates a processed pattern on the substrate;

FIG. 8 illustrates another processed pattern using a light-shielding mechanism;

FIG. 9 illustrates the setting of the light-shielding mechanism for the mask; and

FIG. 10 illustrates processed patterns formed in processing areas on the substrate.

### DESCRIPTION OF THE PREFERRED EMBODIMENTS

Hereinafter, the preferred embodiment of the present invention is described with references to the attached drawings.

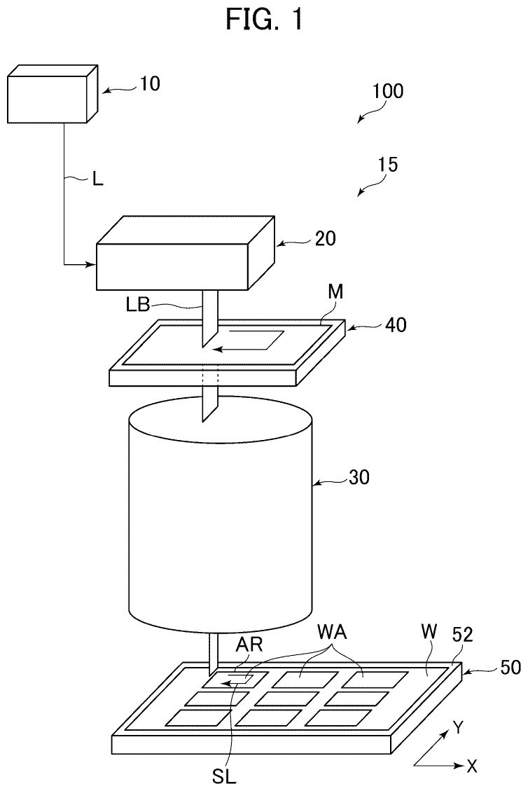

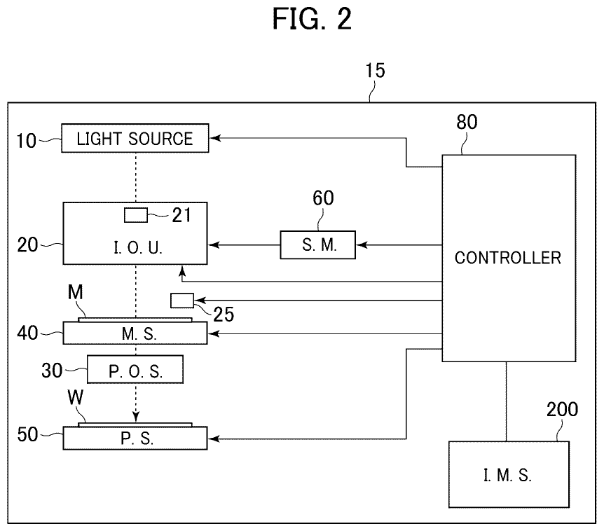

FIG. 1 is a schematic view showing a laser-processing unit according to the first embodiment. FIG. 2 is a block diagram of the laser-processing unit.

A laser-processing unit 100 forms a pattern on a workpiece (herein, substrate) W by laser ablation and is equipped with a light source 10, a body 15, and an information management system 200. An operator manipulates a control device provided in the information management system 200 to input parameters associated with a recipe, including the content and condition of a laser ablation process.

The light source 10 oscillates a laser beam with high energy density. Herein, the light source 10 is an excimer laser that emits a KrF excimer laser beam in a pulse with a wavelength of 248 nm. A laser beam oscillated from the light source 10 is directed toward the body 15 via a laser delivery system (not shown).

The body 15 is equipped with an illumination optical unit 20, a projection optical system 30, a mask stage 40 a processing stage 50 and a scanning mechanism 60 (see FIG. 2), which are supported by a supporting structure (not shown) provided in the body 15. A mask M and a substrate W are mounted on the mask stage 40 and the processing stage 50, respectively.

The illumination optical unit 20 is equipped with a line-beam forming optical system (not shown) including an angle-switching mirror 21, a cylindrical lens (not shown), etc. The line-beam forming optical system forms a line-shaped laser beam LB from the laser beam L that enters the illumination optical unit 20 along the main-scanning direction. The line-shaped laser beam LB, which is a laser beam for processing, is directed onto the mask M via a mirror (not shown). For example, a line-shaped laser beam LB measuring 0.75 mm in the longitudinal direction and 1 mm wide may be formed.

The illumination optical unit 20, which is supported by the scanning mechanism 60, reciprocates along the main-scanning direction as the scanning mechanism 60 moves along the scanning direction. Accordingly, the line-shaped laser beam LB moves relative to the mask M and the substrate W. Consequently, the mask M mounted on the mask stage 40 and the substrate W mounted on the processing stage 50 are scanned. Herein, the X-axis and Y-axis are defined along the main-scanning direction and the sub-scanning direction, respectively. Also, the Z-axis is defined along the vertical direction.

The mask stage 40 supports the mask M and may move the mask M along the main-scanning and sub-scanning directions (the X-axis and Y-axis directions) and rotate the mask M around the vertical direction (Z-axis direction) to maneuver the mask M into a given position. The projection optical system 30, which has focus points on the surfaces of the mask M and the substrate W, projects a beam through the mask M onto the substrate W as a pattern beam. Herein, the projection optical system 30 is a reduced-lens optical system, which has a projection magnification less than 1 (e.g., 0.25).

A light-shielding mechanism 25, which deflects incident light away from the mask M, covers part of the scanning areas scanned by the line-shaped laser beam LB on the mask M. The light-shielding mechanism 25 has a plurality of light-shielding plates (e.g., four plates). The light-shielding plates may be moved in the main-scanning direction (the X-axis direction) and the sub-scanning direction (the Y-axis direction) by a moving mechanism (not shown).

The processing stage 50 functions as a workpiece chuck to secure the substrate W to the processing stage 50 by vacuum suction. Also, the processing stage 50 moves the substrate W along the main-scanning and sub-scanning directions (the X-axis and the Y-axis directions) and rotates the substrate W around the vertical direction (Z-axis direction) to position the substrate W relative to the mask M. Furthermore, the processing stage 50 may move along the main-scanning direction (the X-axis direction) step by step to carry out a laser ablation process for the entire substrate W.

The mask M is composed of material(s) that allows the line-shaped laser beam LB to penetrate it (e.g., quartz glass). Then, a shielding film (e.g., a metallic film) that shields the line-shaped laser beam LB and corresponds to the form of the mask pattern is formed on the surface of the mask M. A mask storage (not shown) stores a plurality of masks. A selected mask M is conveyed from the mask storage to the mask stage 40 by a robotic arm (not shown).

In the substrate W, a copper wiring layer is formed on an epoxy resin and an insulation layer is further formed on the copper wiring layer. Also, a plurality of processing are as AR is lined up at given intervals. As described above, the light source 10 irradiates the substrate W with the excimer laser beam with high energy density, which ablates, i.e., removes material from the substrate W, so that a pattern corresponding to a mask pattern (hereinafter, “processed pattern”) is formed on the substrate W.

The angle-switching mirror 21 in the illumination optical unit 20 may switch the position to be irradiated by the line-shaped laser beam LB in the sub-scanning direction (the Y-axis direction). A processed pattern WA for the entire processing area AR is formed by repeatedly scanning along the main-scanning direction (the X-axis direction).

The processing stage 50 moves in the main-scanning direction (the X-axis direction) and the sub-scanning direction (the Y-axis direction) step by step when a processed pattern WA is formed in a processing area AR to carry out a laser ablation process for the entire substrate W.

As for the processed pattern, an interstitial via hole, blind via hole, wiring groove (trench), etc., can be formed on the substrate W. After the laser ablation process for the substrate W is finished, the substrate W is filled with a conductor such as copper.

The information management system 200 manages the selection of a mask, usage status, etc. In the information management system 200, recipe data, which includes the contents of patterns to be formed on the substrate W, the conditions of a laser ablation process, etc., are recorded in a database together with mask-ID information.

An operator may manipulate an input device (not shown) to select a mask to be used in a laser ablation process and set a recipe. A controller 80 controls the light source 10, the illumination optical unit 20 and the scanning mechanism 60 to move the line-shaped laser beam LB along the main-scanning direction (the X-axis direction) in accordance with an input operation for a laser ablation process. Furthermore, the controller 80 controls the movements of the mask stage 40, the processing 50 and the motion of the conveyer.

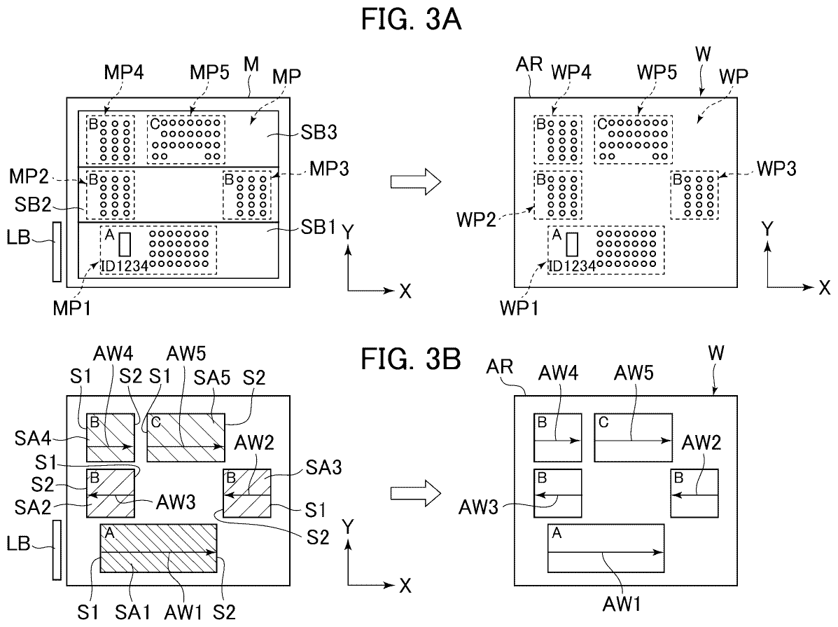

In this embodiment, the laser-processing unit 100 deals with various recipes and may carry out a laser ablation process by using a single mask to form different processed patterns on the substrate W. Hereinafter, this process will be explained with reference to FIGS. 3 to 10.

FIG. 3A illustrates a mask pattern formed on the mask M and a processed pattern formed on the substrate W. FIG. 3B illustrates scanning areas and processing areas. Herein, the line-shaped laser beam LB moves over the mask M in accordance to the formations of mask patterns.

As shown in FIG. 3A, mask patterns MP1 to MP5 are formed apart from one another on the mask M. The mask pattern MP1 includes via-hole array, a rectangular pattern, and an ID pattern for mask management purposes. The mask patterns MP2 to MP5 are patterns of via-hole arrays, respectively. The mask patterns MP2 to MP4 are the same pattern of a via-hole array and the mask pattern MP5 is a pattern of a via-hole array different from the mask patterns MP2 to MP4. The mask pattern MP seen from the entire mask M is a combined pattern including the respective mask patterns MP1 to MP5.

The width of the line-shaped laser beam LB along the sub-scanning direction (the Y-direction) is shorter than the dimensions of the rectangular mask M. Herein, three band-shaped scanning areas SB1 to SB3 are determined for the mask M, and the width of the line-shaped laser beam LB corresponds to each scanning area (hereinafter, called a “scanning band”). The mask pattern MP1 is formed within the scanning band SB1, the mask patterns MP2 and MP3 are formed within the scanning band SB2, and the mask patterns MP4 and MP5 are formed within the scanning band SB3.

When the arrangement of processed patterns to be formed in a processing area WA matches with the arrangement of the mask patterns MP1 to MP5 on the mask M, the entire processed pattern WP in the processing area AR has the same pattern arrangement as that of the entire mask pattern. Namely, processed patterns WP1 to WP5 formed in the processing area AR correspond one-to-one to the mask patterns MP1 to MP5, as shown in FIG. 3A.

FIG. 3B illustrates the moving distance of the line-shaped laser beam LB for each mask pattern when carrying out a laser ablation process for the mask patterns MP1 to MP5. As described above, each of the mask patterns MP1 to MP5 is included in one of the scanning bands SA1, SA2 and SA3. Then, a scanning start position S1 and a scanning end position S2 are determined for each mask pattern. The scanning start position S1 and the scanning end position S2 are defined in accordance to the arrangement of a pattern such as a via hole. An interval between the edges corresponding to the scanning start position and the scanning end position is defined as a “scanning interval”. Herein, scanning intervals SA1 to SA5 are defined.

Based on the arrangement of the mask patterns MP1 to MP5, the scanning bands SB1, SB2 and SB3 are scanned in order, by the line-shaped laser beam LB. To irradiate the mask pattern MP1, the mask pattern MP3, the mask pattern MP2, the mask pattern MP4 and the mask pattern MP5 in order, the line-shaped laser beam LB moves in the forward direction of the X-axis (+X), the reverse direction of the X-axis (−X) and the forward direction of the X-axis (+X).

When carrying out a laser ablation process, firstly, the scanning mechanism 60 moves to match the irradiation position to the scanning start position S1 of the scanning interval SA1. Note that the scanning start position S1 may have a tolerance distance to the actual position of a mask pattern MP1 considering that the scanning mechanism 60 moves while accelerating. The line-shaped laser beam LB1 starts moving from the scanning start point S1 and moves until the scanning end position S2. When the line-shaped laser beam LB reaches the scanning end position S2 (see the arrow AW1), the irradiation by the line-shaped laser beam LB is suspended, i.e., the laser beam L is turned off and the scanning mechanism 60 slows down and stops after the movement of a given distance.

After scanning is completed for the mask pattern MP1, the irradiation position is shifted from the scanning band SB1 to the scanning band SB2 by the angle-switching mirror 21 in the illumination optical unit 20 as the scanning mechanism 60 moves in the forward direction of the X-axis (+X) by a given distance according to the scanning start position S1 of the mask pattern MP3. Note that the X-Y coordinates on the mask M are calibrated for the X-Y coordinates on the substrate W in accordance with the reduced-magnification of the projection optical system 30.

Then, the light source 10 is turned on and the scanning mechanism 60 scans the mask pattern MP3 and the mask pattern MP2, in order, with the line-shaped laser beam LB (see arrows AW2 and A3). The line-shaped laser beam LB doesn't scan the gap between the mask pattern MP3 and the mask pattern MP2.

The oscillation of the laser beam L from the light source 10 is suspended when the line-shaped laser beam LB reaches on the scanning end position S2 of the mask pattern MP3, and the scanning mechanism 60 moves along the reverse direction of the X-axis (−X). The scanning mechanism 60 moves to the scanning start point S2 of the mask pattern MP2 to turn the laser beam L on and resume scanning.

When the line-shaped laser beam LB reaches on the scanning end position S2 of the mask pattern MP2, the irradiation by the line-shaped laser beam LB is again suspended. The angle-switching mirror 21 shifts the scanning position from the scanning band SB2 to the scanning band SB3. Then, the scanning restarts from the scanning start position S1 of the mask pattern MP4 and the irradiation by the line-shaped laser beam LB restarts (see arrow AW4).

When the line-shaped laser beam LB reaches the scanning end position S2 of the mask pattern MP4, the irradiation by the laser beam LB is again suspended. An interval between the mask pattern MP4 and the mask pattern MP5 is not scanned while the scanning mechanism 60 moves over the interval. After the line-shaped laser beam LB moves from the scanning start point S1 to the scanning end position S2 of mask pattern MP5 (see arrow AW5), the laser ablation process for one processing area AR is terminated.

In this way, the scanning is carried out only in each scanning interval and the irradiation position is moved to the scanning start position of the next mask pattern by movement of the scanning mechanism 60, switching the angle of the angle-switching mirror 21, and movement of the processing stage 50. Thus, throughput is enhanced.

As described above, the mask patterns MP1, MP3 and MP4 have the same patterns, and the scanning intervals SA1, SA3 and SA4 are also the same. Therefore, one mask pattern among the mask patterns MP1, MP3 and MP4 may be utilized as a common pattern template. Hereinafter, a laser ablation process in which the arrangement of a processed pattern is different from the arrangement of the mask patterns is explained.

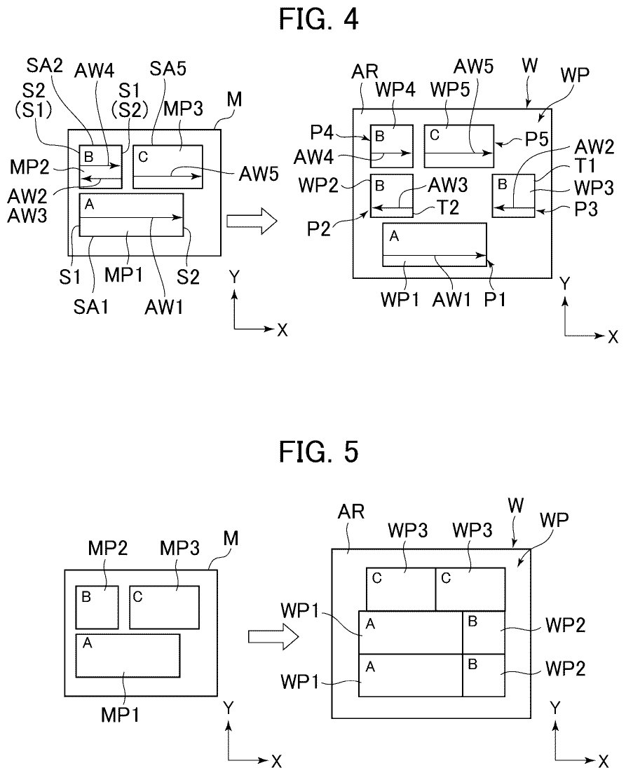

FIG. 4 illustrates a mask with a mask pattern different from the mask pattern in FIG. 3A. Note that the same numerical references are used for the same elements as described above.

The mask M has mask patterns MP1, MP2 and MP3. The mask pattern MP3 and MP4 shown in FIG. 3A is not formed on the mask M since each of the mask patterns MP3 and MP4 is the same as the mask pattern MP2.

Herein, a processed pattern the same as the processed pattern shown in FIG. 3B is formed in a processing area AR by moving the processing stage 50 in addition to the movement of the scanning mechanism 60 and the switching of the angle-switching mirror. These movements or switching adjustments are controlled by the controller 18 to position the line-shaped laser beam LB at the scanning start point of each mask pattern.

Firstly, the line-shaped laser beam LB moves over the mask pattern MP1 (see arrow AW1). Consequently, a processed pattern WP1 is formed on the processing section P1. Then, the processing stage 50 moves in the forward direction of the X-axis (+X) by a given distance and the scanning position is shifted from the scanning band SB1 to the scanning band SB2 after the scanning of mask pattern MP1 is finished (see arrow AW1), i.e., the line-shaped laser beam LB reaches the scanning end position S2 of the scanning interval SA1 and the irradiation of the mask M by the line-shaped laser beam LB is suspended.

The irradiation position moves to the scanning start position S1 of the scanning interval SA2, which coincides with the processing start position T1 of the processing section P1. The line-shaped laser beam LB progresses in the reverse direction of the X-axis (−X) to the scanning end position S2 of the scanning interval SA2 by moving the scanning mechanism 60 in the reverse direction of the X-axis (−X) (see arrow AW2). Thus, a processed pattern WP3 is formed in the processing section P3.

After scanning the mask pattern MP2, the scanning mechanism 60 moves in the forward direction of the X-axis (+X) and the processing stage 50 moves in the reverse direction of the X-axis (−X) so that the irradiation position is moved to the scanning starting position S2 of the scanning interval SA2, which corresponds to the processing start point T2 of the processing section P2. The line-shaped laser beam LB progresses toward the scanning end position S2 of the scanning interval SA2 as the scanning mechanism 60 moves in the reverse direction of the X-axis (−X) (See arrow AW3). Consequently, a processed pattern WP2 is formed on the processing section P2 (see arrow AW3).

After the processed pattern WP2 is formed in the processing section P2, the processing stage 50 moves in the reverse direction of the Y-axis (−Y) to match the irradiation position on the mask M with the processing starting position T3 of the processing section P3, in which a processed pattern WP4 is formed. The scanning mechanism 60 moves from the scanning start position (S1), which is the scanning end position when forming the processed pattern WP2, to the scanning end position (S2). The positions of the processing sections P4 and P5 are the same as the positions shown in FIG. 3.

In this way, the processed pattern WP is formed in the processing area AR on the substrate W, based on the mask M with one of the template mask patterns MP1 to MP3. The arrangement of the processed pattern WP is different from that of the mask pattern MP and the same as the arrangement of the processed pattern WP shown in FIG. 3B.

FIG. 5 illustrates a processed pattern different from the processed pattern shown in FIG. 3B.

Herein, twice the amount of scanning is carried out for the mask patterns MP1, MP2 and MP3, respectively, so that a processed pattern WP composed of processed patterns WP1, WP2 and WP3 is formed in the entire processing area AR. The processed patterns WP1, WP2 and WP3 are formed proximate or adjacent to one another, not apart from one another as shown in FIGS. 3A, 3B and FIG. 4.

The processed pattern WP is formed by moving the scanning mechanism 60 and the processing stage 40 and switching the angle-switching mirror 21. Especially, the processed patterns WP1 to WP3 are positioned to be next to one another by moving the processing stage 50 in the forward direction of the Y-axis (+Y) by a given distance together with the switching of the angle-switching mirror 21. Note that the processed patterns WP1 to WP3 may be positioned to overlap with one another.

In this way, the processed pattern WP, in which the pattern arrangement is different from the pattern arrangement of the mask M, is formed in the processing area AR. This allows a processed pattern different from that formed in another processing area AR to be formed on the same substrate W. Also, an interval between the opposite scanning intervals can be short or eliminated in the main-scanning direction (the X-axis direction) and the sub-scanning direction (the Y-axis direction). On the contrary, the interval between the opposite scanning interval may be longer than the interval between the mask patterns MP1 to MP5 on the mask M. Thus, a processed pattern can be formed within a larger area compared to the interval between the mask patterns MP1 to MP5.

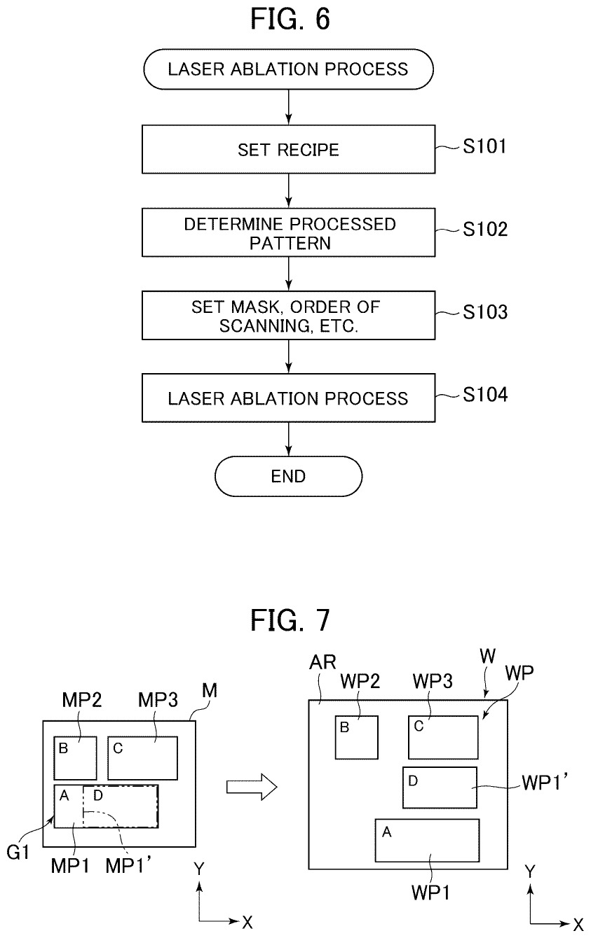

FIG. 6 is a flowchart of a laser ablation process.

A recipe associated with a laser ablation process is selected and set as an operator inputs commands to the information management system 200 (Step 101). The recipe includes various information, such as a mask to be used, arrangement of processed patterns for each processing area, a condition of the laser ablation process, etc. A mask is selected and the arrangement of a processed pattern in the processing area AR is determined in accordance to the recipe (S102). When the arrangement of the processed pattern for each processing area AR is not the same, individual pattern arrangements are determined for each processing area AR.

Based on the determined arrangement of processed pattern in each processing area AR, mask patterns to be used are selected from all the mask patterns formed on the mask M. Simultaneously, scanning times, the order of scanning, etc., are determined (S103). As for the scanning direction, the forward direction or the reverse direction of the X-axis is determined in accordance with the order of scanning in the scanning area in view of throughput.

Based on the determined or selected mask patterns, the order of scanning, etc., a laser ablation process is carried out (Step S104). The processing stage 50, the scanning mechanism 60 and the angle-switching mirror 21 are controlled to match a scanning start position for each scanning interval with a processing start-position of a corresponding processing section, based on the information associated with the scanning start and end positions, the processing start and end positions, and the relative positional relationship between the mask M and the substrate W.

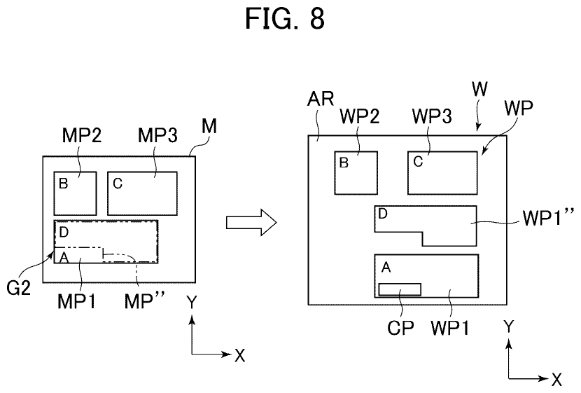

Next, another laser ablation process using a light-shielding mechanism will be explained with reference to FIGS. 7 and 8.

FIG. 7 illustrates a processed pattern on the substrate W.

The mask M has mask patterns MP1, MP2 and MP3, similar to the mask patterns shown in FIGS. 4 and 5. Furthermore, a rectangular mask pattern MP1′, which is part of the mask pattern MP1, is defined on the mask M. An area G1, which is the portion of mask pattern MP1 excluding mask pattern MP1′, may be shielded by moving the light-shielding mechanism 25 when carrying out a laser ablation process. In FIG. 7, four processed patterns WP1, WP1′, WP2 and WP3 are formed in the processing area AR. The processed pattern WP1′ is formed by utilizing the light-shielding mechanism 25.

FIG. 8 illustrates another processed pattern using the light-shielding mechanism 25.

Herein, a mask pattern MP1″, which is a part of the mask pattern MP1, is defined on the mask M. An area G2, which is the portion of mask pattern MP1 excluding mask pattern MP1″, may be shielded by moving the light-shielding mechanism 25 when carrying out a laser ablation process. The area G2 is defined in accordance to a position of a coupon CP, which is a mark used for production management or testing. In FIG. 8, four processed patterns WP1, WP1″, WP2 and WP3 are formed in the processing area AR. The angle-switching mirror 21 is switched to shift the scanning band in a controlled scanning order.

By partially masking a given mask pattern, the length or geometric shape of a mask pattern can be changed to modify a processed pattern. Furthermore, a pattern such as a coupon may be formed at another time and a laser ablation process for the coupon may be omitted.

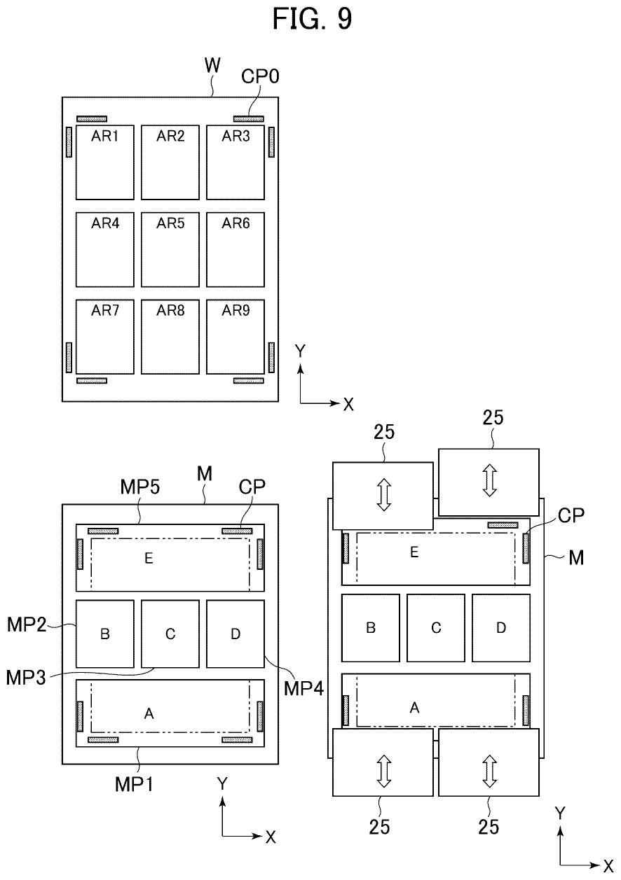

FIG. 9 illustrates the setting of the light-shielding mechanism 25 for the mask.

In the substrate W, the processing areas AR1 to AR9 are arranged in a matrix and apart from one another by a given distance and processing areas CP0 for coupons CP are defined around the processed patterns AR1, AR3, AR7 and AR9. In the mask M, mask patterns MP1 to MP5, which are different from one another, and the coupons CP are formed. The mask M is utilized when carrying out a laser ablation process for each processing area. In a laser ablation process, different processed patterns may be formed in processing areas AR1 to AR9 on the substrate W, or the same processed pattern may be formed in each processing area. When forming a processed pattern in the processing area AR3, the light-shielding members provided in the light-shielding mechanism 25 are arranged at positions shown in FIG. 9.

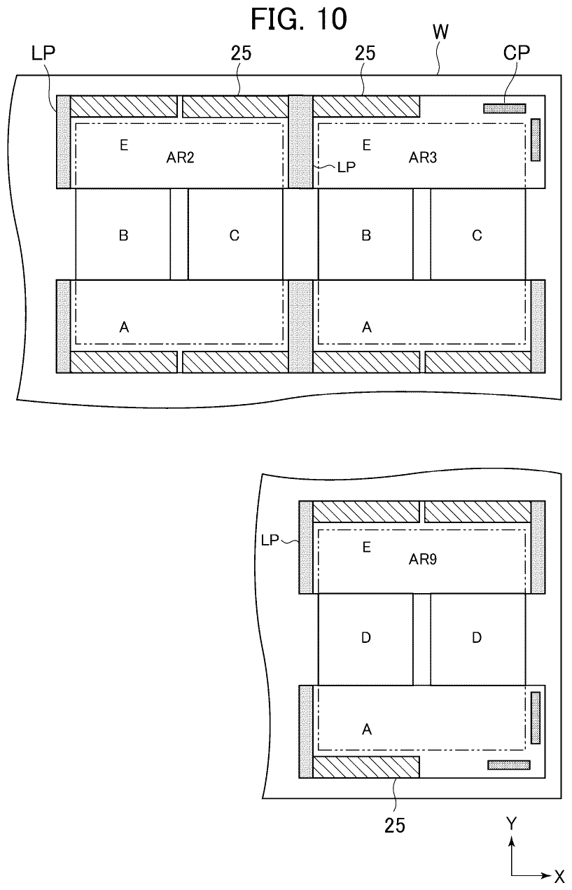

FIG. 10 illustrates processed patterns formed in the processing areas AR2, AR3, and AR9 on the substrate W. As for the processing areas AR2 and AR3, the mask patterns MP1, MP2, MP3 and MP5 are utilized. The mask pattern MP4 is not utilized. On the other hand, as for the processing area AR9, the mask patterns MP1, MP4 and MP5 are utilized. The mask patterns MP2 and MP3 are not utilized.

The light-shielding members may move along the main-scanning direction (the X-axis direction) and the sub-scanning direction (the Y-axis direction) to shield the coupons CP aligned in the main-scanning direction (the X-axis). The positions of the light-shielding members are adjusted independently. The positioning of the light-shielding members shown in FIG. 9 forms coupons around the upper right corner of the processing area AR3.

As for the coupons aligned in the sub-scanning direction (the Y-axis), a scanning interval that does not include coupons CP is defined. A series of areas LP represents areas in which the forming of coupons is avoided or prevented, i.e., the laser beam L is turned off.

As described above, the controller 80 in the laser-processing unit 100 controls the processing stage 50 and/or the scanning mechanism 60 in addition to the switching of the angle-switching mirror 21 and the light-shielding mechanism 25. The scanning start position of each scanning interval on the mask M and the processing start-position for a corresponding processing section in the processing area AR are adjusted based on the recipe data. Thus, a processed pattern, the arrangement of which is different from the arrangement of the mask patterns on the mask M, can be arbitrary formed in a processing area AR defined on the substrate W.

The mask stage 40 may be utilized instead of the processing stage 50 or the scanning mechanism 60, or the mask stage 40 may be combined with the processing stage 50 and the scanning mechanism 60. For example, the scanning start position may be adjusted by moving the mask stage 40. The processing start position of the processing section can be adjusted by controlling the movements of the mask stage 40, the processing stage 50 and the scanning mechanism 60, which allows various processed patterns to be formed in each processing area AR.

Finally, it will be understood by those skilled in the arts that the foregoing description is of preferred embodiments of the device, and that various changes and modifications may be made to the present invention without departing from the spirit and scope thereof.

The present disclosure relates to subject matter contained in Japanese Patent Application No. 2025-007950 (filed on Jan. 20, 2025), which is expressly incorporated herein by reference, in its entirety.

1. A method for processing a workpiece, comprising:
a) preparing a mask with a plurality of mask patterns;
b) scanning a mask with a line-shaped laser beam by a scanning mechanism, said mask being mounted on a mask stage, said plurality of mask patterns being aligned in scanning bands corresponding to the width of the line-shaped laser beam;
c) projecting a pattern beam that passes through said mask onto a workpiece mounted on a processing stage to form a processed pattern in a processing area on said workpiece; and
d) adjusting a processing start-position on said workpiece by controlling at least one of said mask stage, said processing stage or said scanning mechanism, in accordance to processing sections in the processing area, the processing sections being defined for at least one mask pattern.

2. The method according to claim 1, wherein the adjusting comprises adjusting a scanning start-position on said mask by moving said mask stage or said scanning mechanism.

3. The method according to claim 1, wherein the adjusting comprises moving a scanning start-position on said mask to a next scanning start-position that is within the same scanning area and is subjected to be scanned next.

4. The method according to claim 1, wherein the adjusting comprising moving a processing start-position of the line-shaped laser beam on said mask in a direction perpendicular to a scanning direction on said workpiece, by moving said processing stage.

5. The method according to claim 1, wherein the adjusting comprises positioning a processing start position on said workpiece to a contact position or an overlapping position between neighboring processing sections, by moving said processing stage.

6. The method according to claim 1, further comprising shifting the position of the line-shaped laser beam to form a processed pattern in a different processing area by switching a position of an angle-switching mirror, said angle-switching mirror configured to switch a scanning band of the line-shaped laser beam to form processed patterns in different forming sections on said workpiece.

7. The method according to claim 1, wherein the scanning comprises scanning the line-shaped laser beam over single mask pattern repeatedly to form a processed pattern in different processing sections.

8. The method according to claim 1, further comprising:
determining a scanning interval for said mask; and
setting a mask pattern to be used and a scanning order.

9. The method according to claim 8, wherein determining comprises determining a scanning direction for the mask pattern from one of either a forward direction or a reverse direction.

10. The method according to claim 1, wherein determining comprises determining different light-shielding areas for a plurality of processing areas by using a light-shielding member configured to shield part of a scanning area on said mask.

11. The method according to claim 1, further comprising forming processed patterns in processing areas on said workpiece, the arrangement of the processed patterns being different from one another.
